(19) United States
(12) Patent Application Publication
(10) Pub. No.: US 2008/0024990 A1
(43) Pub. Date: Jan. 31, 2008

(54) Water block heat-dissipating structure

(76) Inventors: Yu-Huang Peng, Nan Tou Hsien (TW); Yi-Shen Chien, Taipei Hsien (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/495,679

(22) Filed: Jul. 31, 2006

(51) Int. Cl. H05K 7/20

(52) U.S. Cl. 361/700; 361/699

(57) ABSTRACT

A water block heat-dissipating structure includes a first cover body, a second cover body, and a hollow seat body. The first cover body has a first board body and a plurality of first heat-dissipating fins formed on the first board body. The second cover body has a second board body, a plurality of second heat-dissipating fins formed on the second board body, and at least one water inlet and at least one water outlet respectively penetrated through the second board body, wherein the first heat-dissipating fins and the second heat-dissipating fins are alternate each other. The hollow seat body is sealed and disposed between the first board body and the second board body for completely sealing the first heat-dissipating fins and the second heat-dissipating fins.

### BACKGROUND OF THE INVENTION

1. Field of the Invention

The present invention relates to a water block heat-dissipating structure, and particularly relates to the heat-dissipating fins of a first cover body and a second cover body being alternate and opposite each other. The heat-dissipating fins are assembled together to form the water block heat-dissipating structure with a plurality of micro runners between each two fins.

2. Description of the Related Art

Over the years, the processing velocity of CPUs has become faster, thus generating larger amounts of heat. In order to dissipate the heat from the heat source to the external world, a heat-dissipating device and a fan are usually used to help dissipate the heat. However, the fan is noisy and consumes lots of power due to its high rotational speed. It has so far proven difficult for designers to solve these problems of noise and power consumption.

Referring to FIGS. 1-2, a known water block heat-dissipating structure is disclosed that solved the above-mentioned questions. The water block heat-dissipating structure includes a seat body 1 and a seal cover body 2. The seat body 1 has a plurality of heat-dissipating fins 10 formed thereon, and a bottom portion of the seat body 1 contacts a heat-generating source (not shown). In addition, the seal body 2 is seals and covers the seat body 1. The seal body 2 further has a water inlet 20 and a water outlet 21.

When the bottom portion of the seat body 1 contacts a heat-generating source (not shown), heat is transmitted from the heat-generating source to the heat-dissipating fins 10. In addition, the heat of the first heat-dissipating fins 10 can be guided away quickly (absorbed) by cooling liquids that circulate between the water inlet 20 and the water outlet 21 (as shown by the arrows of FIG. 2).

However, the fins 10 all face in the same direction, and between each two adjacent fins 10 there is a gap D that is not compact enough and limited due to the use of the traditional process. Hence, the known water block heat-dissipating structure cannot include micro runners between each two fins 10 (this means that the known structure cannot produce a large enough heat-dissipating area). Hence, the know water block heat-dissipating structure's heat exchange performance is limited and poor.

### SUMMARY OF THE INVENTION

The present invention provides a water block heat-dissipating structure. The water block heat-dissipating structure uses a plurality of heat-dissipating fins that are alternate each other and assembled together to form the water block heat-dissipating structure with a plurality micro runners between each two fins. Hence, after cooling liquids flow into the water block heat-dissipating structure, a stay time of the cooling liquids in the water block heat-dissipating structure will be increased due to dual effects of fin's stop and micro runner's turbulence for increasing heat-dissipating effect among the cooling liquids and fins.

A first aspect of the present invention is a water block heat-dissipating structure, comprising: a first cover body and a second cover body. The first cover body has a first board body and a plurality of first heat-dissipating fins formed on the first board body. The second cover body has a second board body, a plurality of second heat-dissipating fins formed on the second board body, and at least one water inlet and at least one water outlet respectively penetrated through the second board body. The second cover body and the first cover body are jointed and sealed together, and the first heat-dissipating fins and the second heat-dissipating fins are alternate each other.

A second aspect of the present invention is a water block heat-dissipating structure, comprising: a first cover body, a second cover body, and a hollow seat body. The first cover body has a first board body and a plurality of first heat-dissipating fins formed on the first board body. The second cover body has a second board body, a plurality of second heat-dissipating fins formed on the second board body, and at least one water inlet and at least one water outlet respectively penetrated through the second board body, wherein the first heat-dissipating fins and the second heat-dissipating fins are alternate each other. The hollow seat body is sealed and disposed between the first board body and the second board body for completely sealing the first heat-dissipating fins and the second heat-dissipating fins.

A third aspect of the present invention is a water block heat-dissipating structure, comprising: a first cover body, a plurality of second heat-dissipating fins, and a hollow seat body. The first cover body has a first board body and a plurality of first heat-dissipating fins formed on the first board body. The second heat-dissipating fins are respectively stacked on the first heat-dissipating fins, wherein the second heat-dissipating fins are disposed on the first board body, and the second heat-dissipating fins and the first heat-dissipating fins are alternate each other. The hollow seat body has at least one water inlet and at least one water outlet respectively penetrated therethrough, wherein the hollow seat body is jointed and sealed on the first board body for completely sealing the first heat-dissipating fins and the second heat-dissipating fins.

It is to be understood that both the foregoing general description and the following detailed description are exemplary, and are intended to provide further explanation of the invention as claimed. Other advantages and features of the invention will be apparent from the following description, drawings and claims.

### BRIEF DESCRIPTION OF THE DRAWINGS

The various objects and advantages of the present invention will be more readily understood from the following detailed description when read in conjunction with the appended drawings, in which:

FIG. 1 is a perspective, exposed view of a water block heat-dissipating structure of the prior art;

FIG. 2 is a perspective, assembled view of a water block heat-dissipating structure of the prior art;

FIG. 3 is a perspective, assembled view of a water block heat-dissipating structure according to the first embodiment of the present invention;

FIG. 4 is a cross-sectional view along line 4-4 of FIG. 3;

FIG. 5 is an exposed view of FIG. 4;

FIG. 6 is a cross-sectional view along line 6-6 of FIG. 3;

FIG. 7 is a perspective, assembled view of a water block heat-dissipating structure according to the second embodiment of the present invention;

FIG. 8 is a cross-sectional view along line 8-8 of FIG. 7;

FIG. 9 is a perspective, exposed view of a water block heat-dissipating structure according to the third embodiment of the present invention;

FIG. 10 is a perspective, assembled view of a water block heat-dissipating structure according to the third embodiment of the present invention;

FIG. 11 is a cross-sectional view along line 11-11 of FIG. 10;

FIG. 12 is a cross-sectional view of a water block heat-dissipating structure according to the fourth embodiment of the present invention;

FIG. 13 is a perspective, assembled view of a water block heat-dissipating structure according to the fifth embodiment of the present invention;

FIG. 14 is a cross-sectional view along line 14-14 of FIG. 13;

FIG. 15 is an exposed view of FIG. 14; and

FIG. 16 is a cross-sectional view of a water block heat-dissipating structure according to the sixth embodiment of the present invention.

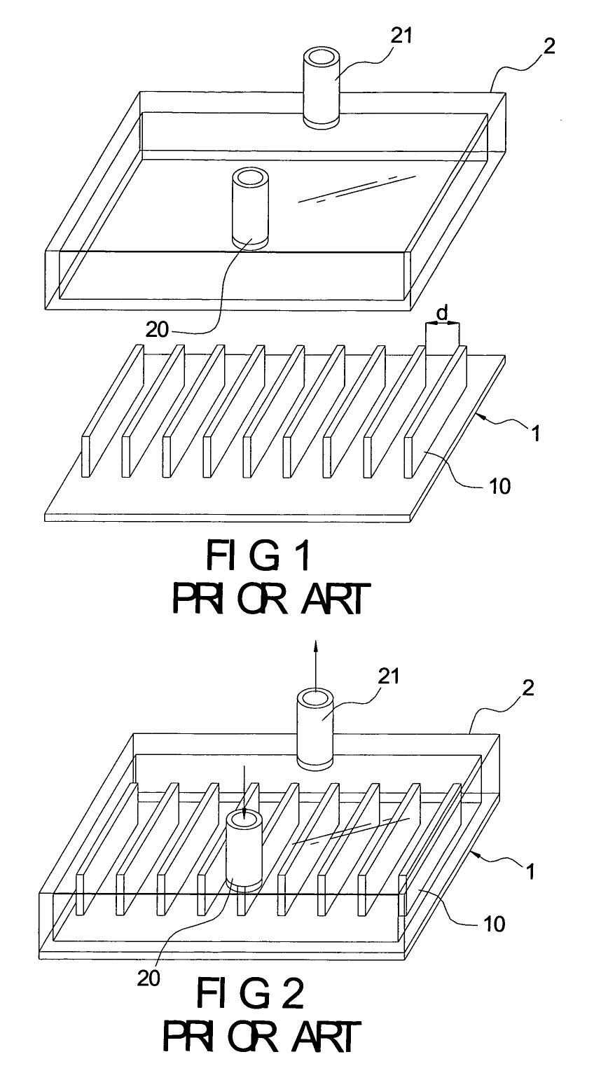

### DETAILED DESCRIPTION OF PREFERRED BEST MOLDS

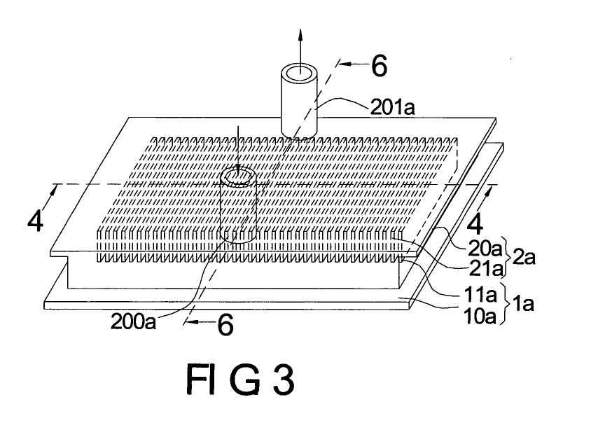

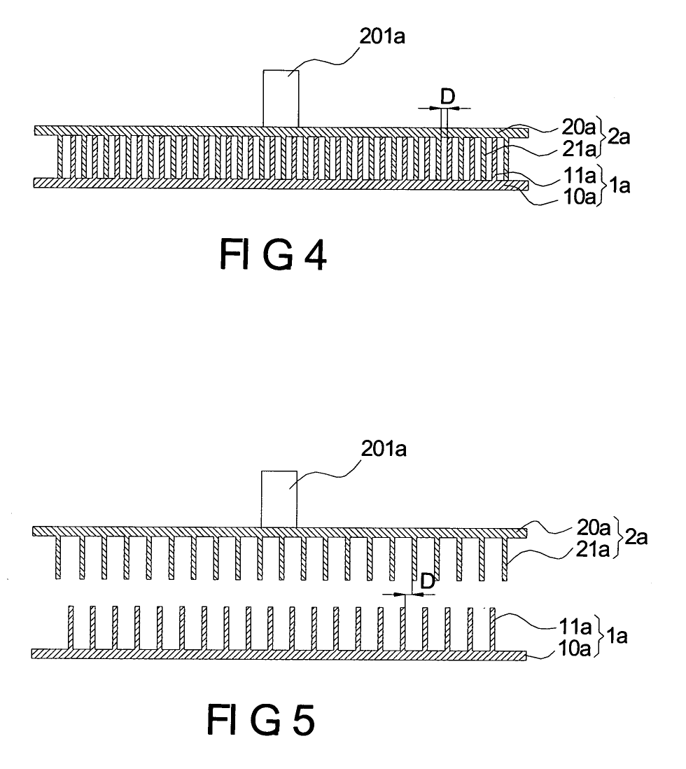

Referring to FIGS. 3-6, the first embodiment of the present invention provides a water block heat-dissipating structure that comprises a first cover body 1a and a second cover body 2a.

The first cover body 1a has a first board body 10a and a plurality of first heat-dissipating fins 11a formed on the first board body 10a. The second cover body 2a has a second board body 20a, a plurality of second heat-dissipating fins 21a formed on the second board body 20a, and at least one water inlet 200a and at least one water outlet 201a respectively penetrated through the second board body 20a. Moreover, the second cover body 2a and the first cover body 1a seal and completely jointed together, and the first heat-dissipating fins 11a and the second heat-dissipating fins 21a are alternate each other. Between each two adjacent first heat-dissipating fins 11a and the second heat-dissipating fin 21a there is a gap D that is between 0.05-2 mm. In addition, each first heat-dissipating fin 11a can be formed and attached on the first board body 10a and each second heat-dissipating fin 21a can be formed and attached on the second board body 20a via solders (not shown) or any other kind of heat-conducting adhesive.

Moreover, the first heat-dissipating fins 11a can be formed on the first board body 10a and the second heat-dissipating fins 21a are formed on the second board body 20a in any arrangement. For example, the first heat-dissipating fins 11a can be vertically formed on the first board body 10a and the second heat-dissipating fins 21a can be vertically formed on the second board body 20a; alternatively the first heat-dissipating fins 11a can be obliquely formed on the first board body 10a, and the second heat-dissipating fins 21a can be horizontal to the first heat-dissipating fins 11a and obliquely formed on the second board body 20a.

Furthermore, the first heat-dissipating fins 11a and the second heat-dissipating fins 21a are alternate each other at regular or differing intervals. In addition, the first heat-dissipating fins 11a can be selectively formed on a first predetermined area (not shown) of the first board body 10a and the second heat-dissipating fins 21a can be selectively formed on a second predetermined area (not shown) of the second board body 20a, and the second predetermined area corresponds to the first predetermined area. In other words, the first heat-dissipating fins 11a and the second heat-dissipating fins 21a can be selectively formed on the first board body 10a and the second board body 20a respectively according to user's need.

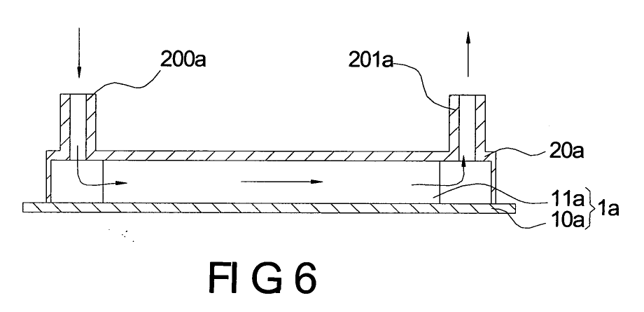

In addition, the water inlet 200a is disposed on one lateral side of a top side of the second board body 20a, and the water outlet 201a is disposed on another lateral side of the top side of the second board body 20a. Thereby, when a bottom portion of the first board body 10a contacts a heat-generating source (not shown), heat is transmitted from the heat-generating source to the first heat-dissipating fins 11a and the second heat-dissipating fins 21a through the first board body 10a. In addition, the heat of the first heat-dissipating fins 11a and the second heat-dissipating fins 21a can be guided away quickly (absorbed) by cooling liquids that circulate between the water inlet 200a and the water outlet 201a (as indicated by the arrows of FIGS. 3 and 6). Moreover, because the first heat-dissipating fins 11a and the second heat-dissipating fins 21a are compact, the contact areas are increased between the fins 11a, 21a and the cooling liquids. Hence, the water block heat-dissipating structure of the present invention has a good heat exchange performance.

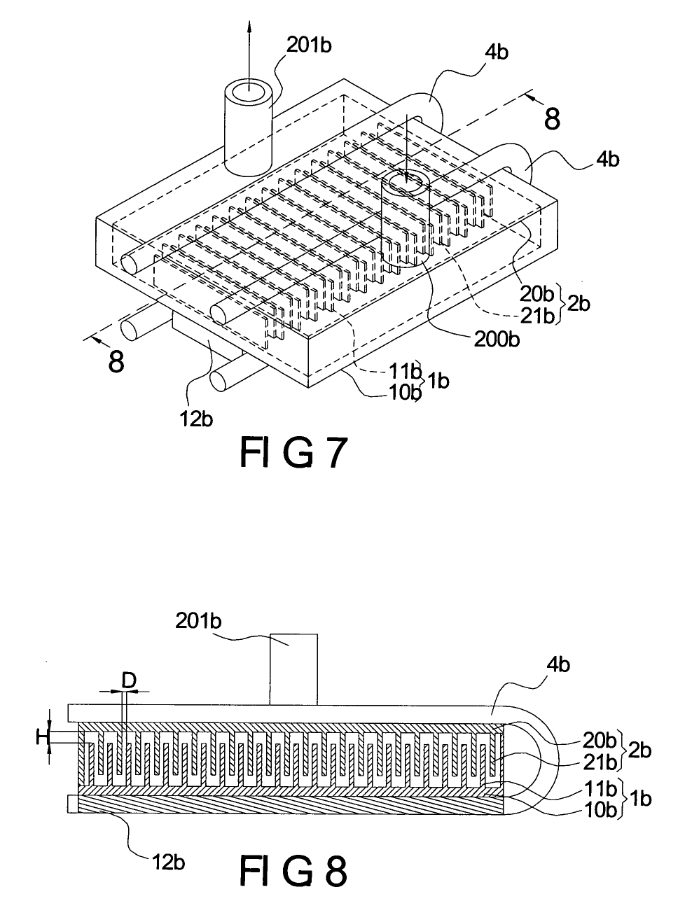

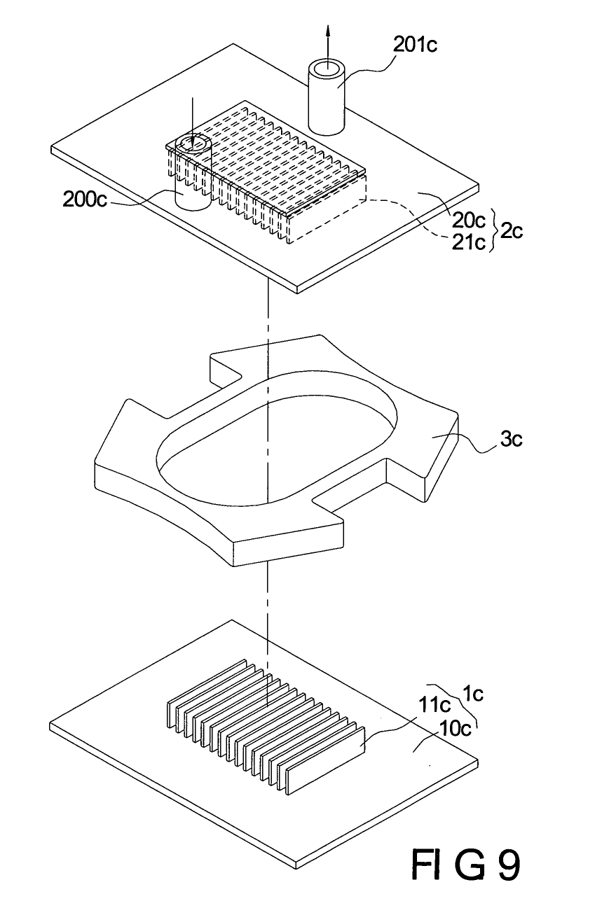

Referring to FIGS. 7-8, the second embodiment of the present invention provides a water block heat-dissipating structure that comprises a first cover body 1b, a second cover body 2b, and two heat pipes 4b. The first cover body 1b has a first board body 10b and a plurality of first heat-dissipating fins 11b formed on the first board body 10b. The second cover body 2b has a second board body 20b, a plurality of second heat-dissipating fins 21b formed on the second board body 20b, and at least one water inlet 200b and at least one water outlet 201b respectively penetrated through the second board body 20b. Between each two adjacent first heat-dissipating fin 11b and second heat-dissipating fin 21b there is a gap D that is between 0.05-2 mm.

The difference between the second embodiment and the first embodiment is that each first heat-dissipating fin 11b and each second heat-dissipating fin 21b is respectively separated from the second board body 20b and the first board body 10b in a predetermined distance H. In addition, the two heat pipes 4b contact a bottom portion of the first board body 10b and a bottom portion of the second board body 20b. Thereby, when the bottom portion of the first board body 10b contacts a heat-generating source (not shown), heat is transmitted from the heat-generating source to the first heat-dissipating fins 11b via the first board body 10b and to the second heat-dissipating fins 21b via both the first board body 10b and the two heat pipes 4b. In addition, the heat of the first heat-dissipating fins 11b and the second heat-dissipating fins 21b can be guided away quickly (absorbed) by cooling liquids that circulate between the water inlet 200b and the water outlet 201b (as indicated by the arrows of FIG. 7). Hence, the water block heat-dissipating structure of the present invention has a good heat exchange performance.

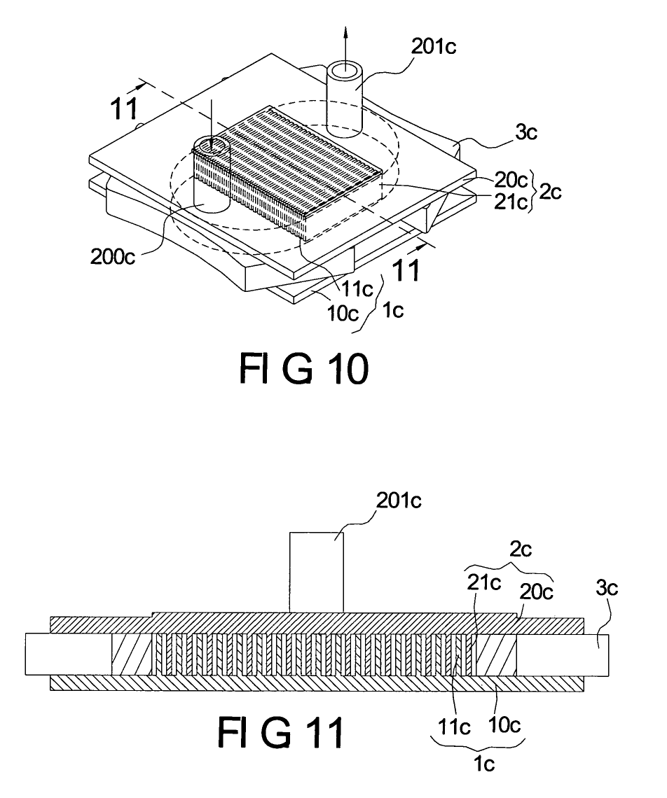

Referring to FIGS. 9-11, the third embodiment of the present invention provides a water block heat-dissipating structure that comprises a first cover body 1c, a second cover body 2c, and a hollow seat body 3c.

The first cover body 1c has a first board body 10c and a plurality of first heat-dissipating fins 11c formed on the first board body 10c. The second cover body 2c has a second board body 20c, a plurality of second heat-dissipating fins 21c formed on the second board body 20c, and at least one water inlet 200c and at least one water outlet 201c respectively penetrated through the second board body 20c. In addition, the first heat-dissipating fins 11c and the second heat-dissipating fins 21c are alternate each other. The hollow seat body 3c is sealed and disposed between the first board body 10c and the second board body 20c for completely sealing the first heat-dissipating fins 11c and the second heat-dissipating fins 21c.

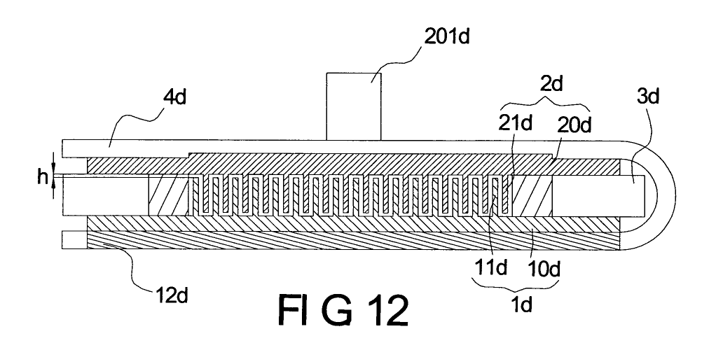

Referring to FIG. 12, the fourth embodiment of the present invention provides a water block heat-dissipating structure that comprises a first cover body 1d, a second cover body 2d, a hollow seat body 3d, and two heat pipes 4d. The first cover body 1d has a first board body 10d and a plurality of first heat-dissipating fins 11d formed on the first board body 10d. The second cover body 2d has a second board body 20d, a plurality of second heat-dissipating fins 21d formed on the second board body 20d, and at least one water inlet (not shown) and at least one water outlet 201d respectively penetrated through the second board body 20d. In addition, the first heat-dissipating fins 11d and the second heat-dissipating fins 21d are alternate each other. The hollow seat body 3d is sealed and disposed between the first board body 10d and the second board body 20d for completely sealing the first heat-dissipating fins 11d and the second heat-dissipating fins 21d.

The difference between the fourth embodiment and the third embodiment is that each first heat-dissipating fin 11d and each second heat-dissipating fin 21d are respectively separated from the second board body 20d and the first board body 10d by a predetermined distance h. In addition, the two heat pipes 4d contact a bottom portion of the first board body 10d and a bottom portion of the second board body 20d. Thereby, when the bottom portion of the first board body 10d contacts a heat-generating source (not shown), heat is transmitted from the heat-generating source to the first heat-dissipating fins 1d via the first board body 10d and the second heat-dissipating fins 21d via both the first board body 10d and the two heat pipes 4d. In addition, the heat from the first heat-dissipating fins 1d and the second heat-dissipating fins 21d can be guided away quickly (absorbed) by cooling liquids that circulate between the water inlet (not shown) and the water outlet 201d. Hence, the water block heat-dissipating structure of the present invention has a good heat exchange performance.

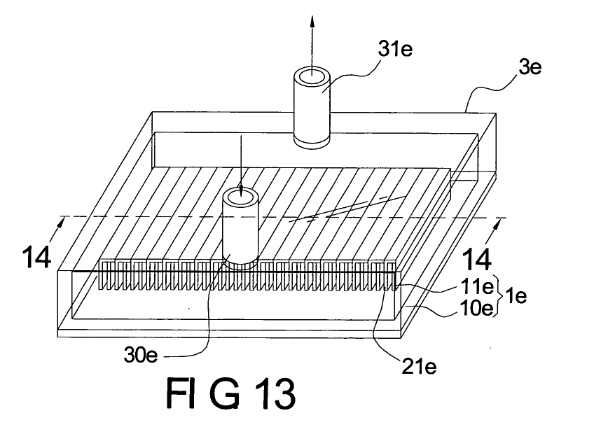

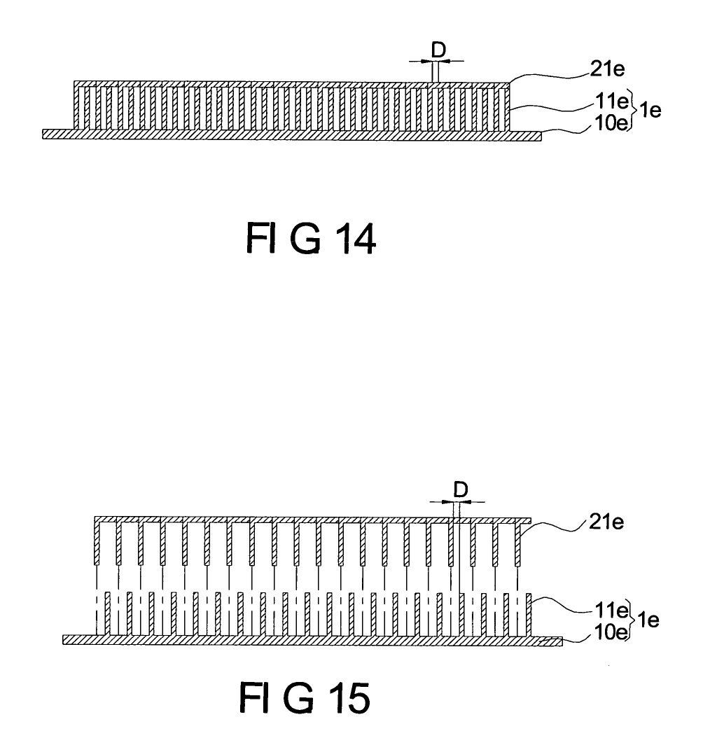

Referring to FIGS. 13-15, the fifth embodiment of the present invention provides a water block heat-dissipating structure that comprises a first cover body 1e, a plurality of second heat-dissipating fins 21e, and a hollow seat body 3e.

The first cover body 1e has a first board body 10e and a plurality of first heat-dissipating fins 11e formed on the first board body 10e. The second heat-dissipating fins 21e are respectively stacked on the first heat-dissipating fins 11e. In addition, the second heat-dissipating fins 21e are disposed on the first board body 10e, and the second heat-dissipating fins 21e and the first heat-dissipating fins 11e are alternate each other. The hollow seat body 3e has at least one water inlet 30e and at least one water outlet 31e respectively penetrated therethrough. The hollow seat body 3e are jointed and sealed on the first board body 10e for completely sealing the first heat-dissipating fins 11e and the second heat-dissipating fins 21e. Between each two adjacent first heat-dissipating fins 1e and each second heat-dissipating fin 21e there is a gap D.

Thereby, when a bottom portion of the first board body 10e contacts a heat-generating source (not shown), heat is transmitted from the heat-generating source to the first heat-dissipating fins 11e and the second heat-dissipating fins 21e through the first board body 10e. In addition, the heat of the first heat-dissipating fins 11e and the second heat-dissipating fins 21e can be guided away quickly (absorbed) by cooling liquids that circulate between the water inlet 30e and the water outlet 31e (as indicated by the arrows in FIG. 13). Moreover, because the first heat-dissipating fins 11e and the second heat-dissipating fins 21e are compact, the size of the contact areas are increased among the fins 11e, 21e and the cooling liquids. Hence, the water block heat-dissipating structure of the present invention has a good heat exchange performance.

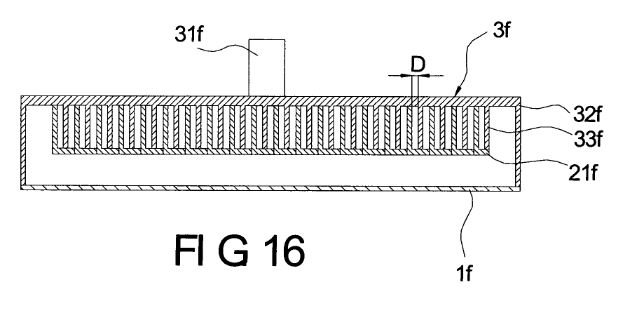

Referring to FIG. 16, the sixth embodiment of the present invention provides a water block heat-dissipating structure that comprises a first cover body If, a plurality of second heat-dissipating fins 21f, and a hollow seat body 3f.

The difference between the sixth embodiment and the fifth embodiment is that the first cover body If is a plane board and the hollow seat body 3f has a first board body 32f and a plurality of first heat-dissipating fins 33f formed on the first board body 32f. In addition, the second heat-dissipating fins 21f are respectively stacked on the first heat-dissipating fins 33f. The second heat-dissipating fins 21f are disposed on the first board body 32f, and the second heat-dissipating fins 21f and the first heat-dissipating fins 33f are alternate each other.

What the sixth embodiment and the fifth embodiment have in common is that hollow seat body 3f has at least one water inlet (not shown) and at least one water outlet 31f respectively penetrated therethrough. In addition, the hollow seat body 3f is sealed and jointed on the first cover body If for completely sealing the first heat-dissipating fins 33f and the second heat-dissipating fins 21f. Between each two adjacent first heat-dissipating fins 33f and the second heat-dissipating fin 21f there is a gap D.

Thereby, when a bottom portion of the first board body 32f contacts a heat-generating source (not shown), heat is transmitted from the heat-generating source to the first heat-dissipating fins 33f and the second heat-dissipating fins 21f through the first board body 32f. In addition, the heat of the first heat-dissipating fins 33f and the second heat-dissipating fins 21f can be guided away quickly (absorbed) by cooling liquids that circulate between the water inlet (not shown) and the water outlet 31f. Moreover, because the first heat-dissipating fins 33f and the second heat-dissipating fins 21f are compact, the size of the contact areas are increased between the fins 33f, 21f and the cooling liquids. Hence, the water block heat-dissipating structure of the present invention has a good heat exchange performance.

In conclusion, the water block heat-dissipating structure uses a plurality of heat-dissipating fins that are alternate each other and assembled together to form the water block heat-dissipating structure with a plurality micro runners between each two fins. Hence, after cooling liquids flow into the water block heat-dissipating structure, a stay time of the cooling liquids in the water block heat-dissipating structure will be increased due to dual effects of fin's stop and micro runner's turbulence for increasing heat-dissipating effect among the cooling liquids and fins.

Moreover, the present invention uses fins that are alternative each other for making the fins structure become compact and tiny. In addition, the present invention also can use heat pipes to transmit heat from a bottom portion to a top portion, and the heat from the top portion is transmitted to fins to precede heat exchange. Hence, the heat exchange efficiency of the present invention is better than that of prior art.

Although the present invention has been described with reference to the preferred best molds thereof, it will be understood that the invention is not limited to the details thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A water block heat-dissipating structure, comprising:
a first cover body having a first board body and a plurality of first heat-dissipating fins formed on the first board body; and
a second cover body having a second board body, a plurality of second heat-dissipating fins formed on the second board body, and at least one water inlet and at least one water outlet respectively penetrated through the second board body, wherein the second cover body and the first cover body are sealed and completely jointed together, and the first heat-dissipating fins and the second heat-dissipating fins are alternate each other.

2. The water block heat-dissipating structure as claimed in claim 1, wherein the first heat-dissipating fins are vertically formed on the first board body and the second heat-dissipating fins are vertically formed on the second board body, or the first heat-dissipating fins are obliquely formed on the first board body and the second heat-dissipating fins are horizontal to the first heat-dissipating fins and obliquely formed on the second board body.

3. The water block heat-dissipating structure as claimed in claim 1, wherein between each two adjacent first heat-dissipating fins and the second heat-dissipating fin there is a gap of between 0.05 mm and 2 mm.

4. The water block heat-dissipating structure as claimed in claim 1, wherein the first heat-dissipating fins and the second heat-dissipating fins are alternate each other at regular or differing intervals.

5. The water block heat-dissipating structure as claimed in claim 1, wherein each first heat-dissipating fin is formed and attached on the first board body and each second heat-dissipating fin is formed and attached on the second board body via solders respectively; wherein the first board body has a bottom portion contacted with a heat-generating source for transmitting heat from the heat-generating source to the first heat-dissipating fins and the second heat-dissipating fins through the first board body; wherein the first heat-dissipating fins are selectively formed on a first predetermined area of the first board body and the second heat-dissipating fins are selectively formed on a second predetermined area of the second board body, and the second predetermined area corresponds to the first predetermined area.

6. The water block heat-dissipating structure as claimed in claim 1, wherein each first heat-dissipating fin and each second heat-dissipating fin are respectively separated from the second board body and the first board body by a predetermined distance.

7. The water block heat-dissipating structure as claimed in claim 6, further comprising at least one heat pipe that contacts a bottom portion of the first board body and a bottom portion of the second board body, wherein the bottom portion of the first board body contacts a heat-generating source for transmitting heat from the heat-generating source to the first heat-dissipating fins via the first board body and to the second heat-dissipating fins via both the first board body and the at least one heat pipe.

8. A water block heat-dissipating structure, comprising:
a first cover body having a first board body and a plurality of first heat-dissipating fins formed on the first board body;
a second cover body having a second board body, a plurality of second heat-dissipating fins formed on the second board body, and at least one water inlet and at least one water outlet respectively penetrated through the second board body, wherein the first heat-dissipating fins and the second heat-dissipating fins are alternate each other; and
a hollow seat body is sealed and disposed between the first board body and the second board body for completely sealing the first heat-dissipating fins and the second heat-dissipating fins.

9. The water block heat-dissipating structure as claimed in claim 8, wherein the first heat-dissipating fins are vertically formed on the first board body and the second heat-dissipating fins are vertically formed on the second board body, or the first heat-dissipating fins are obliquely formed on the first board body and the second heat-dissipating fins are horizontal to the first heat-dissipating fins and obliquely formed on the second board body.

10. The water block heat-dissipating structure as claimed in claim 8, wherein between each two adjacent first heat-dissipating fins and the second heat-dissipating fin there is a gap of between 0.05 mm and 2 mm.

11. The water block heat-dissipating structure as claimed in claim 8, wherein the first heat-dissipating fins and the second heat-dissipating fins are alternate each other at regular or differing intervals.

12. The water block heat-dissipating structure as claimed in claim 8, wherein each first heat-dissipating fin is formed and attached on the first board body and each second heat-dissipating fin is formed and attached on the second board body via solders respectively; wherein the first board body has a bottom portion that contacts a heat-generating source for transmitting heat from the heat-generating source to the first heat-dissipating fins and the second heat-dissipating fins through the first board body; wherein the first heat-dissipating fins are selectively formed on a first predetermined area of the first board body and the second heat-dissipating fins are selectively formed on a second predetermined area of the second board body, and the second predetermined area corresponds to the first predetermined area.

13. The water block heat-dissipating structure as claimed in claim 8, wherein each first heat-dissipating fin and each second heat-dissipating fin are respectively separated from the second board body and the first board body by a predetermined distance.

14. The water block heat-dissipating structure as claimed in claim 13, further comprising at least one heat pipe that contacts a bottom portion of the first board body and a bottom portion of the second board body, wherein the bottom portion of the first board body contacts a heat-generating source for transmitting heat from the heat-generating source to the first heat-dissipating fins via the first board body and to the second heat-dissipating fins via both the first board body and the at least one heat pipe.

15. A water block heat-dissipating structure, comprising:
a first cover body having a first board body and a plurality of first heat-dissipating fins formed on the first board body;
a plurality of second heat-dissipating fins respectively stacked on the first heat-dissipating fins, wherein the second heat-dissipating fins are disposed on the first board body, and the second heat-dissipating fins and the first heat-dissipating fins are alternate each other; and
a hollow seat body having at least one water inlet and at least one water outlet respectively penetrated therethrough, wherein the hollow seat body is jointed and sealed on the first board body for completely sealing the first heat-dissipating fins and the second heat-dissipating fins.

16. The water block heat-dissipating structure as claimed in claim 15, wherein the first heat-dissipating fins are vertically formed on the first board body and the second heat-dissipating fins are vertically formed on the first board body, or the first heat-dissipating fins are obliquely formed on the first board body and the second heat-dissipating fins are horizontal to the first heat-dissipating fins and obliquely formed on the first board body.

17. The water block heat-dissipating structure as claimed in claim 15, wherein between each two adjacent first heat-dissipating fins and the second heat-dissipating fin there is a gap of between 0.05 mm and 2 mm.

18. The water block heat-dissipating structure as claimed in claim 15, wherein the first heat-dissipating fins and the second heat-dissipating fins are alternate each other at regular or differing intervals.

19. The water block heat-dissipating structure as claimed in claim 15, wherein each first heat-dissipating fin is formed and attached on the first board body and each second heat-dissipating fin is formed and attached on the second board body via solders respectively; wherein the first board body has a bottom portion that contacts a heat-generating source for transmitting heat from the heat-generating source to the first heat-dissipating fins and the second heat-dissipating fins through the first board body; wherein the first heat-dissipating fins are selectively formed on a first predetermined area of the first board body and the second heat-dissipating fins are selectively formed on a second predetermined area of the second board body, and the second predetermined area corresponds to the first predetermined area.
